(19) United States
(12) Patent Application Publication
(10) Pub. No.: US 2004/0148578 A1
(43) Pub. Date: Jul. 29, 2004

(54) Method and system for design selection by interactive visualization

(76) Inventors: Trent Lorne McConaghy, Ottawa (CA); Glen Michael Hertz, Ottawa (CA)

Correspondence Address: BORDEN LADNER GERVAIS LLP, WORLD EXCHANGE PLAZA, 100 QUEEN STREET SUITE 1100, OTTAWA, ON, K1P 1J9, CA

(21) Appl. No.: 10/479,582

(22) PCT Filed: Jun. 17, 2002
(86) PCT No.: PCT/CA02/00891

(51) Int. Cl. G06F 17/50; H01L 25/00

(52) U.S. Cl. 716/1; 326/41

(57) ABSTRACT

A method and system for electronic circuit design selection by interactive visualization. The present invention is particularly appropriate for learning the performance and behaviour of analog circuits, and for selecting a preferred design from a dataset of candidate designs derived from a multi-objective optimization. The method consists of providing a multidimensional dataset from a multiobjective optimization, or otherwise. The multidimensional dataset is then displayed as a plurality of plots. The plots can be one-dimensional, or multi-dimensional, and can include parallel coordinate plots. By modifying at least one of the plots, the user can interactively select an evaluation dataset for further evaluation or testing. The modification can take the form of interactive filtering to reduce the dataset in a desired manner. Typically, this is done through a graphical interface, by visual selection, brushing, etc. It can also include defining or constructing constraints of one or more variables in the multidimensional dataset. The constraints can include linear and non-linear. This modification and selection process can be repeated as necessary to further restrict the dataset to a manageable number of candidate designs.

### FIELD OF THE INVENTION

The present invention relates to design systems and methodologies. In particular, the present invention relates to a method and system for selecting designs from a number of candidate designs by an interactive visualization technique. The present invention is particularly applicable to analog, digital and mixed signal circuit design selection of candidate designs derived from a multi-objective optimization.

### BACKGROUND OF THE INVENTION

Today's electronic chip designers require the development of effective approaches for information visualization and knowledge discovery that allow the user of electronic design automation (EDA) software to interact more directly and effectively with the design database in order to understand the performance characteristics of their design. This is particularly important when multi-objective optimization techniques are used that provide a very large number of candidate designs. The circuit metrics determined for each candidate design provide a multidimensional dataset that is rich in information, but, due to its size and complexity can be difficult for a designer to efficiently sort through to find the designs that are most desirable.

The use of visual perception systems to view large multidimensional, or multivariate, datasets is well known. There exist a number of methods for visualizing such datasets, such as multiple views, Chernoff faces, star plots, cell mean plot, Aiken and West's plot, Johnson-Neyman plot, parallel coordinates, fisheye display, association rules, wavelet based multi-resolution display, pixel-level visualization scheme, and tree maps. However, the application of such systems and methods to permit EDA software users to dynamically query an underlying database of candidate designs and isolate designs of interest by exploiting a visual interface have not been explored.

Information visualization has become an increasingly interesting research area. Such visualization techniques are found to be useful in many applications in science, engineering, management, and Internet technology. For the semiconductor industry, silicon capacity is progressively doubling every 18 months and allowing more complex systems to be built on a single chip of silicon. However, the capacity to design such complex systems in reasonable time diminishes with complexity. This gap between capacity and productivity seems to threaten the growth of the semiconductor industry. Ideally information visualization can be used to effectively help close this gap as an integral part of electronic design automation tools.

It is, therefore, desirable to provide a method and system for interactive visualization to permit the efficient selection of designs from a group of multidimensional candidate designs, particularly in the field of digital or analog circuit design.

### SUMMARY OF THE INVENTION

It is an object of the present invention to obviate or mitigate at least one disadvantage of previous design methodologies and systems.

In a first aspect, there is provided a method for electronic circuit design selection through interactive visualization of multidimensional datasets. The method consists of providing a multidimensional dataset from a multiobjective optimization, or otherwise. The multidimensional dataset is then displayed as a plurality of plots. The plots can be one-dimensional, or multi-dimensional, and can include parallel coordinate plots. By modifying at least one of the plots, the user can interactively select an evaluation dataset for further evaluation or testing. The modification can take the form of interactive filtering to reduce the dataset in a desired manner. Typically, this is done through a graphical interface, by visual selection, brushing, etc. It can also include defining or constructing constraints of one or more variables in the multidimensional dataset. The constraints can include linear and non-linear. This modification and selection process can be repeated as necessary to further restrict the dataset to a manageable number of candidate designs. A system for implementing the method of the present invention is also disclosed.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached drawings, wherein:

FIG. 1 shows a parallel coordinate plot of circuit data according to the present invention;

FIG. 2 shows a parallel coordinate plot demonstrating a visualization relationship between metrics and design variables according to the present invention;

FIG. 3 shows a parallel coordinate plot demonstrating a visualization relationship between metrics and random variables according to the present invention;

FIG. 4 shows a parallel coordinate plot demonstrating a visualization relationship between metrics and environmental variables according to the present invention;

FIG. 5 shows a parallel coordinate plot demonstrating a visualization relationship between metrics, random, design and environmental variables according to the present invention;

FIG. 6 shows a parallel coordinate plot demonstrating a further visualization relationship between metrics, random, design and environmental variables according to the present invention;

FIG. 7 shows a plot of coordinates 9 and 10 of the previous circuit data;

FIGS. 8-20 illustrate a first example of the visualization method according to the present invention; and

FIGS. 22-35 illustrate a second example of the visualization according to the present invention.

### DETAILED DESCRIPTION

Generally, the present invention provides a method and system for design selection by interactive visualization. The present invention is particularly appropriate for learning the performance and behaviour of analog circuits, and for selecting a preferred design from a dataset of candidate designs derived from a multi-objective optimization. In one embodiment, the visualization is based on a parallel coordinate system that enables a user to view the tradeoff analysis of circuit metrics, and parameters in multiple dimensions in an effective way. Several ways to utilize this visualization system for the study of circuit performances and design qualities are also addressed, particularly of designs derived through analog design synthesis.

The system of the present invention generally consists of a database that stores a multidimensional dataset, such as a set of predetermined circuit variables for a number of potential circuit designs. A general purpose computer executing a data visualization application program such as ggobi, a well known open source program, permits the design variables of each design in the multidimensional dataset to be displayed as plots on a conventional computer monitor, or display. Interaction between the user and the graphical user interface displaying the plots permits the dataset to be viewed in multiple formats and restricted to certain desired designs. User interaction is provided by conventional user input devices, such as mouse, keypad, etc., and through tools provided through the data visualization software, such as brushing, glyph selection, colour manipulation, etc., as described more fully in the ggobi manual available at http://www.ggobi.org/.

Embodiments of the invention may be implemented in any conventional computer programming language. For example, preferred embodiments may be implemented in a procedural programming language (e.g. “C”) or an object oriented language (e.g. “C++”). Alternative embodiments of the invention may be implemented as pre-programmed hardware elements, other related components, or as a combination of hardware and software components.

Embodiments can be implemented as a computer program product for use with a computer system. Such implementation may include a series of computer instructions fixed either on a tangible medium, such as a computer readable medium (e.g., a diskette, CD-ROM, ROM, or fixed disk) or transmittable to a computer system, via a modem or other interface device, such as a communications adapter connected to a network over a medium.

The medium may be either a tangible medium (e.g., optical or electrical communications lines) or a medium implemented with wireless techniques (e.g., microwave, infrared or other transmission techniques). The series of computer instructions embodies all or part of the functionality described herein. Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

It is expected that such a computer program product may be distributed as a removable medium with accompanying printed or electronic documentation (e.g., shrink wrapped software), preloaded with a computer system (e.g., on system ROM or fixed disk), or distributed from a server over the network (e.g., the Internet or World Wide Web). Of course, some embodiments of the invention may be implemented as a combination of both software (e.g., a computer program product) and hardware. Still other embodiments of the invention may be implemented as entirely hardware, or entirely software (e.g., a computer program product).

The method for design selection through interactive visualization of multidimensional datasets of the present invention generally consists of providing a multidimensional dataset from a multiobjective optimization, or otherwise. The multidimensional dataset is then displayed as a plurality of plots. The plots can be one-dimensional, or multi-dimensional, and can include parallel coordinate plots. By modifying at least one of the plots, the user can interactively select an evaluation dataset for further evaluation or testing. The modification can take the form of interactive filtering to reduce the dataset in a desired manner. Typically, this is done through a graphical interface, by visual selection, brushing, etc. It can also include defining or constructing constraints of one or more variables in the multidimensional dataset. The constraints can be linear or non-linear. The modification and selection process can be repeated as necessary to further restrict the dataset to a manageable number of candidate designs.

Generally, it should be noted that the parallel coordinates plot is very effective for visualizing circuit data sets because it offers low computational complexity that is O(N) where N is the number of dimensions (variables) represented by the same number of parallel axes. Further reasons are that it works for any N, variables are treated uniformly, and displayed objects can be recognized under projective transformations. This permits multidimensional tradeoff analog circuit data to be represented and visually explored by the parallel-coordinate based visualization to help the designer make better decisions in the complex design process with a timing constraint.

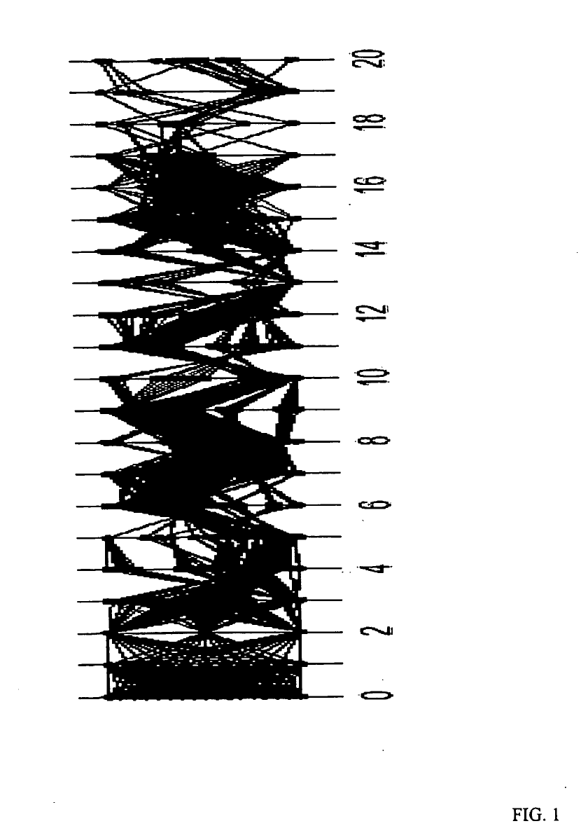

Parallel coordinates display is a technique pioneered in the 1970's which has been applied to a diverse set of multidimensional problems. In this method, each dimension corresponds to an axis, and the N axes are organized as uniformly spaced vertical lines. A data element in N-dimensional space manifests itself as a connected set of points, one on each axis. Points lying on a common line or plane create readily perceived structures in the image. The major limitation of the parallel coordinates technique is that large data sets can cause difficulty in interpretation; as each point generates a line, lots of points can lead to rapid clutter. Also, relationships between adjacent dimensions are easier to perceive than between non-adjacent dimensions. The number of dimensions that can be visualized is fairly large, limited by the horizontal resolution of the screen, although as the axes get closer to each other it becomes more difficult to perceive structure or clusters. FIG. 1 shows a typical parallel-coordinate display of an analog circuit data set of 561 vectors that consists of 21 dimensions (variables) which are encoded along a horizontal line whereas the corresponding values are specified along the vertical lines. The circuit index, manufacturing index, and operating point index are encoded in the first, second, and third coordinate respectively; metrics are shown from the 4th to the 15th coordinate; random variables from the 16th to the 17th coordinate; and the design variables from the 18th to the 21st coordinate. Together with the use of dynamic brushing of colours and glyphs, the user can easily interact with the information displayed to focus on and to track the behaviours of certain data items. It is also useful in that when some coordinates or vectors are hidden or excluded so that the designer can easily focus on the data of interest. The following sections demonstrate more details of how information visualization can be useful in the study of key relationships between metrics and random variables, and the testing of their relational hypotheses.

Based on the visual display of the parallel coordinates, the user can interact with the visualization tool to study the following relationships:

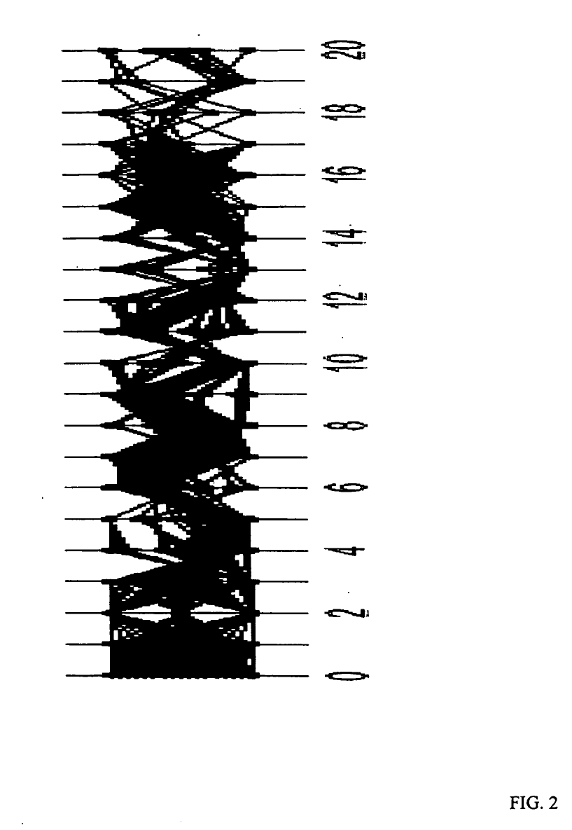

Between metrics and design variables (see FIG. 2). From interacting with the figure it becomes evident that a low percent overshoot (coordinate 9) is only achievable if the two last design variables are high (coordinates 19 and 20).

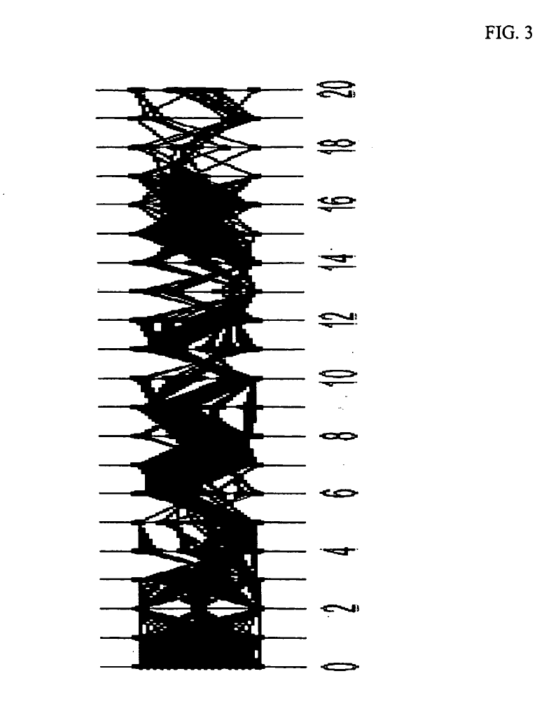

Between metrics and random variables (see FIG. 3). The randomness has a small influence on the performance of the circuit.

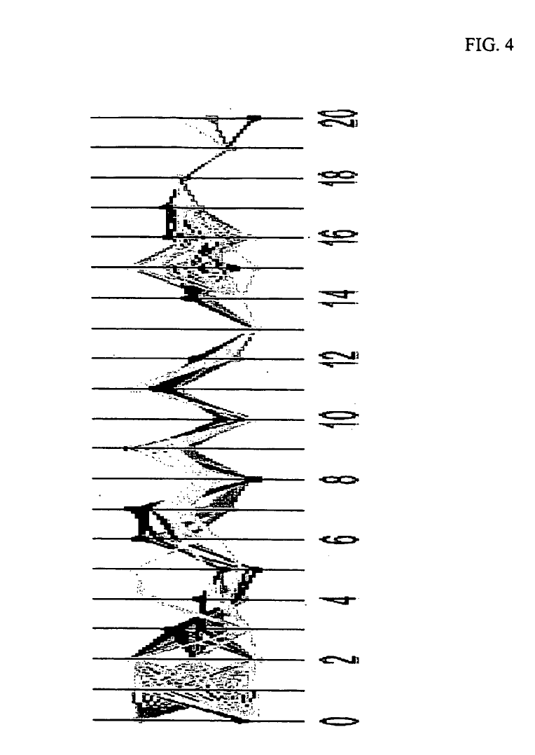

Between metrics and environmental variables (operating points). The operating point has a large influence on the performance of the circuit for metrics on the 5th and 6th coordinate (see FIG. 4).

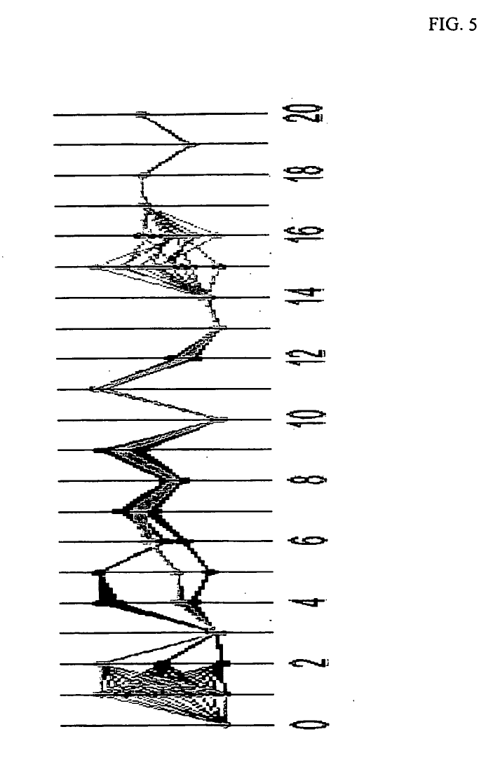

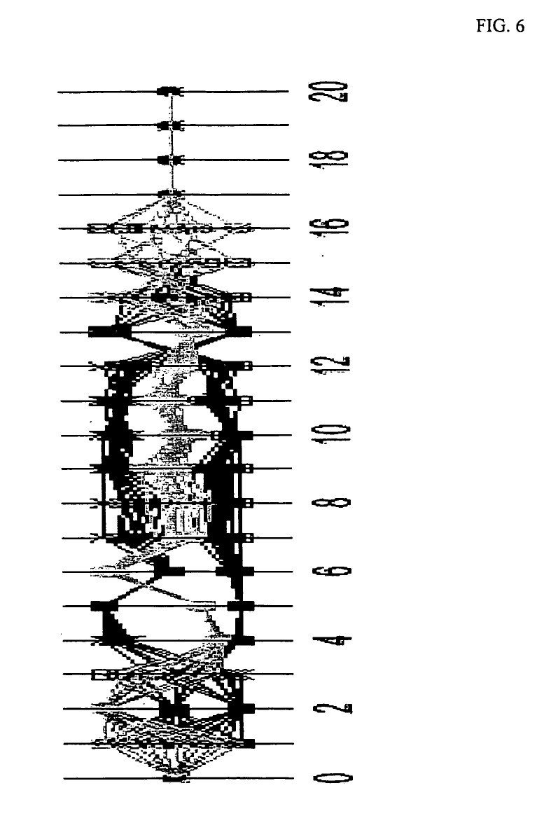

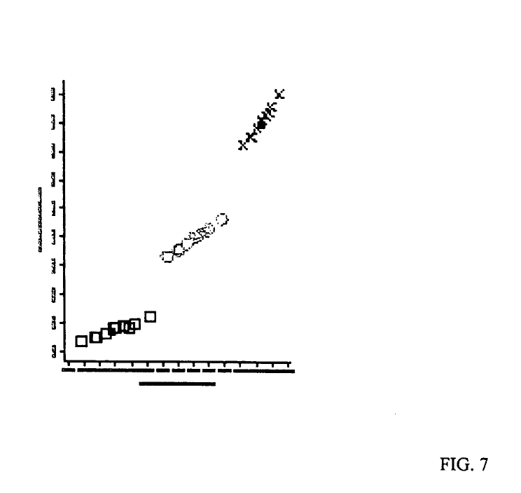

Between design variables, random variables, environmental variables, and metrics (see FIG. 5). The designs are influenced more by the operating point than the noise introduced by manufacturing. The coordinates of FIG. 5 are zoomed in and plotted in FIG. 6. In FIG. 6 the user can see that the line segments joining coordinates 7 through 10 do not cross one another which quickly tells us that there is a positive correlation between all of the metrics. The positives correlation between two of the these coordinates is displayed as a scatter plot in FIG. 7.

Information display is only one component of the task that includes data query as an integral part. The reason is that a data visualization system should do more than simply plot the data, but should have some decision analysis components to generate the results from learning the interaction of the datasets, identifying the right feature dimensions, discovering hidden patterns, and making inferences from the built models. As a particular example, the user can detect trends and patterns in the design data that will help answer some questions about the design. When used in this mode, a query is created to access the records relevant to the question being formulated. After the data is retrieved, they are examined for patterns or other useful information that can be used in answering the original question.

Using the information displayed and interactive features, the user can test the hypotheses about the relationships between different design variables as follows.

How operating points influence the performance of circuit candidates per metric or overall variables. Once the performance of the circuit under different operating conditions is better understood the environmental parameters such as battery voltage, and temperature ranges can be specified such that the circuit performance is adequate.

How manufacturing conditions influence the performance of circuit candidates per metric or over all variables. This can be used to calculate expected yields and to improve designs to obtain higher yields.

What typical performance is for each or all operating points in terms of statistical measures such as min, max, mean, median, and standard deviation. This is very useful because it gives a good indicator of the minimum, typical, and maximum performance of the circuit.

In this verification task, the user generates a hypothesis about the data, issues a query against the data and examines the results of the query looking for affirmation or negation of the hypothesis. In the first case, the process ends; in the latter case, a new query is reformulated and the process iterates until the resulting data either verifies the hypothesis or the user decides that the hypothesis is not valid for the given data. Expert designers may be surprised to find that the rule of thumb they rely on to predict circuit behaviour is not valid.

The method of the present invention can be best illustrated by reference to the following two examples of analog circuit design selection. In these examples circuit metrics and other variables, for multiple candidate designs were derived through a multiobjective optimization or synthesis technique, are provided. Each candidate design was simulated at three operating points. In the first example, 200 candidate designs were evaluated at three operating points, resulting in 600 datasets. In the second example, 17 candidate designs were evaluated at 11 random instances and three operating points.

### EXAMPLE 1

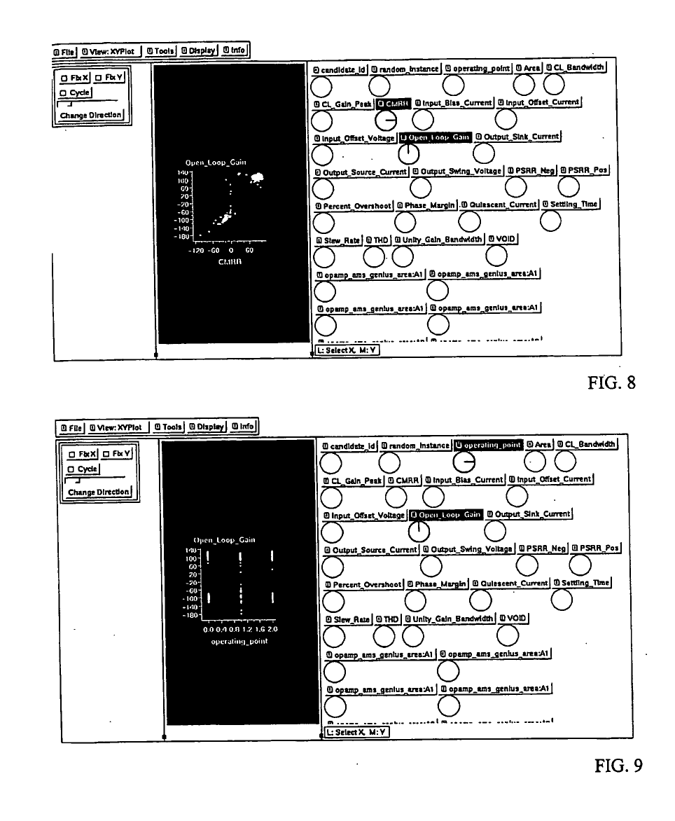

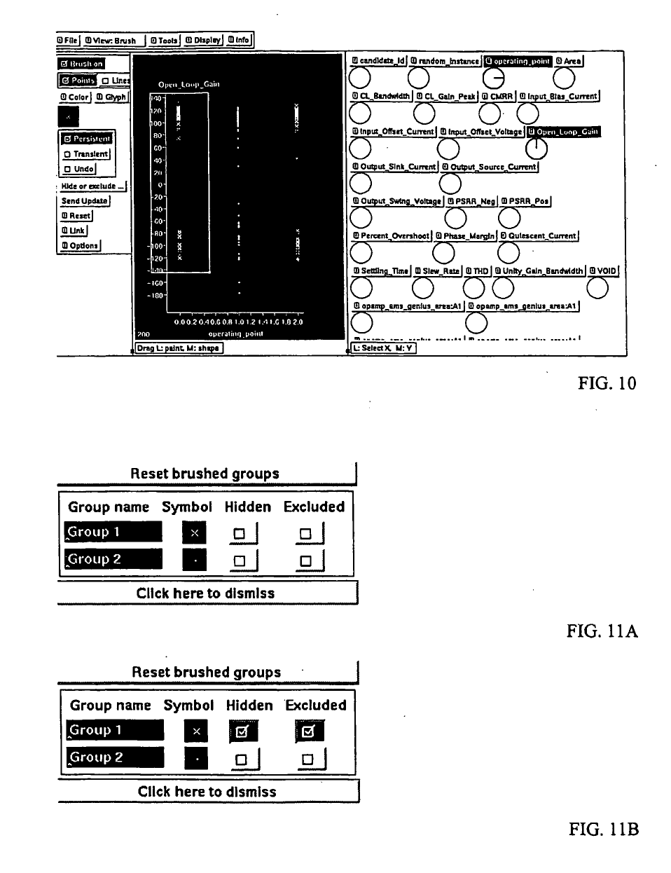

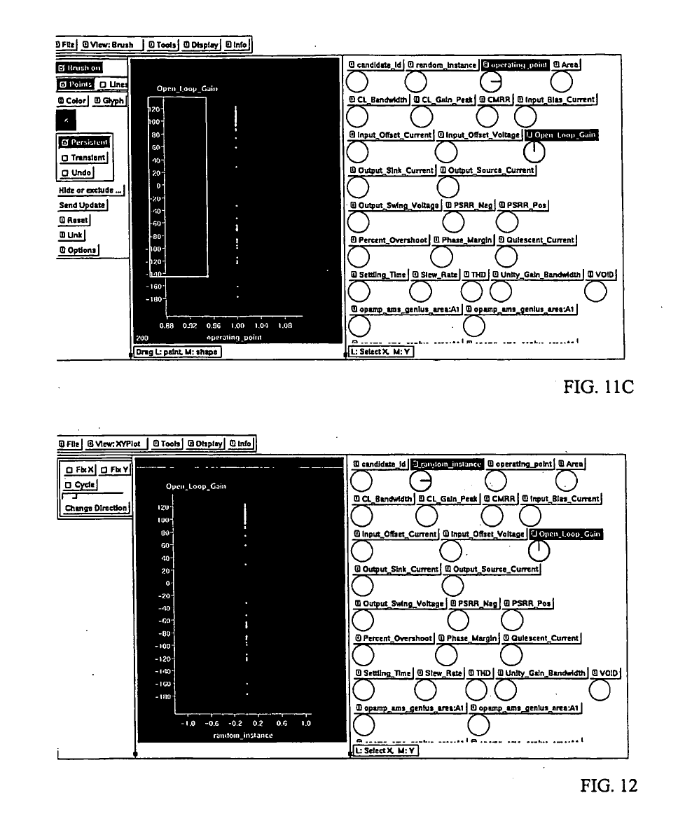

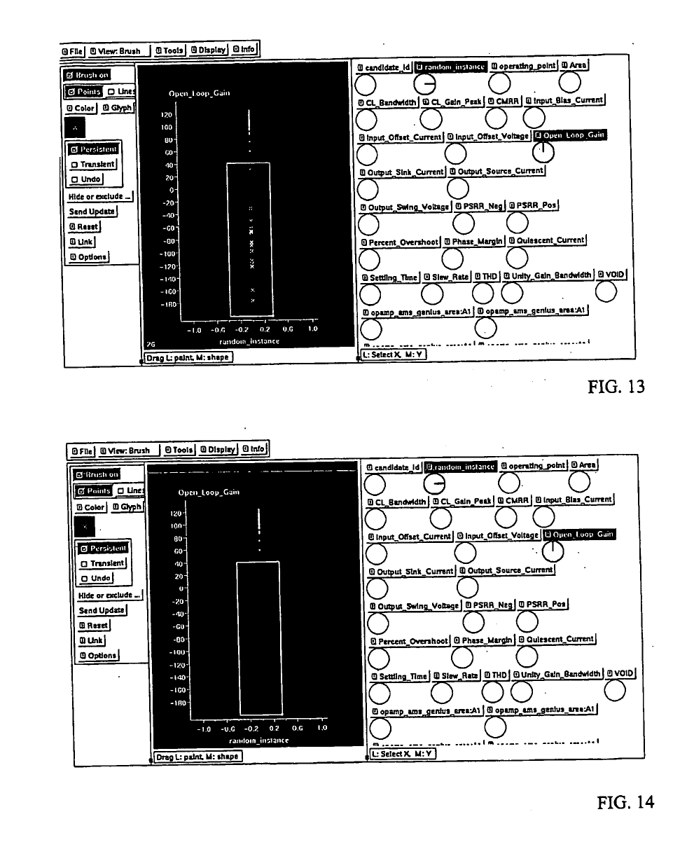

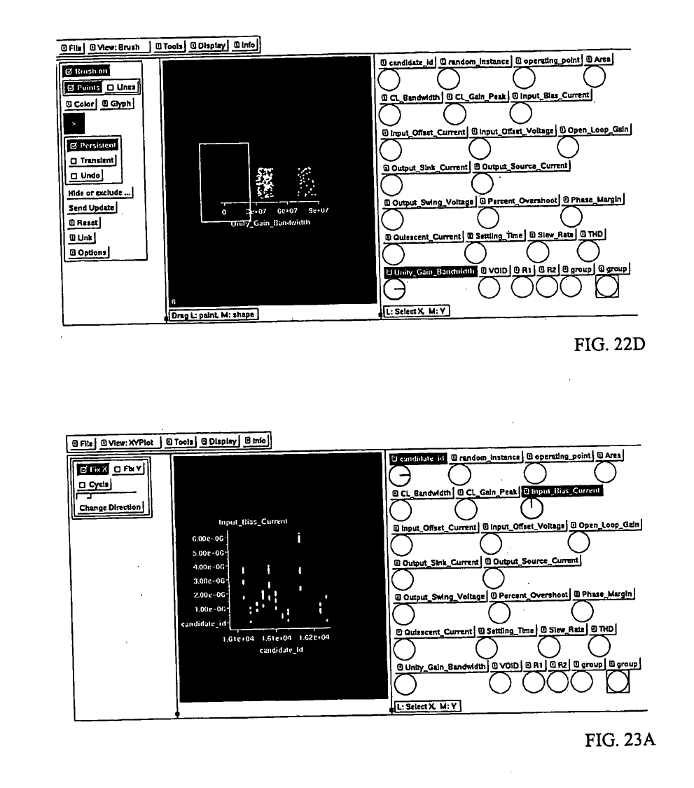

Example 1 is illustrated in FIGS. 8-20. In FIG. 8 the 600 datasets are displayed in a 2-D plot of CMRR vs. open loop gain, or any other arbitrary variables. In FIG. 9, the user makes “operating point” one of the axes on the plot (the other axis is arbitrary) in order to view the three operating points. In this example, the user wants to visualize based on one operating point, so first selects the datapoints of the other two operating points by applying a brush tool to change the glyph of the other two points to an “x”, as shown in FIG. 10. The brush tool permits the user to “brush” over certain datapoints and change their display characteristics through interaction with dialogue boxes as shown in FIGS. 11A and 11B, or other conventional means such as dropdown menus, etc. In this example, the user assigns the selected datapoints to Group1 and excludes them from the view so that the automatic scaling does not take them into account. This results in a display of 200 datapoints, as shown in FIG. 11C.

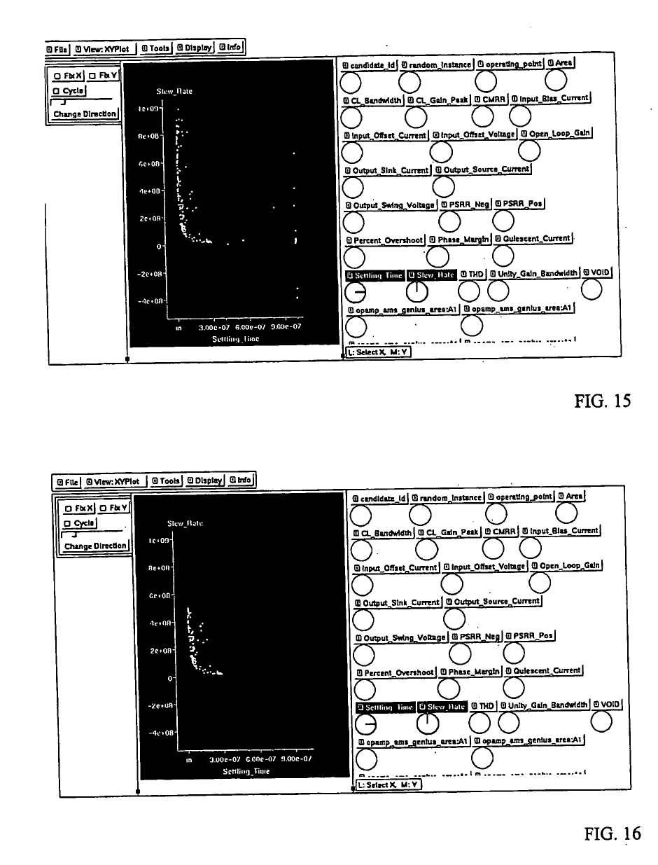

Next, the user changes the x-axis of the displayed plot from operating point to the variable random instance, as shown in FIG. 12 (the axes of interest are selected from among the listed variables at the right of the display). A random instance is a Monte Carlo sample drawn from a distribution which models the random variation in manufacturing the circuit. The user can now see that there is only one random instance in this particular dataset, so that random instances are no longer a concern in this particular design selection.

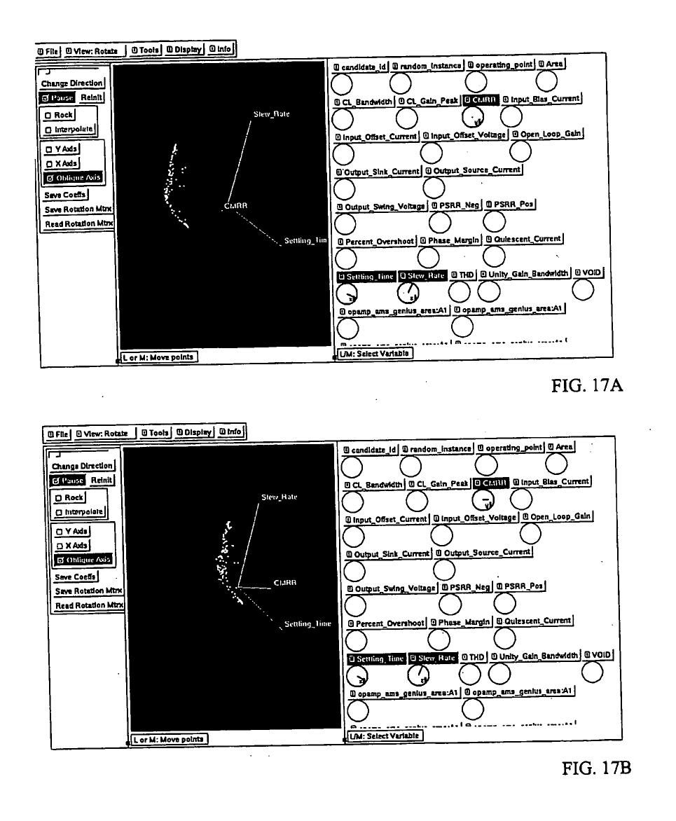

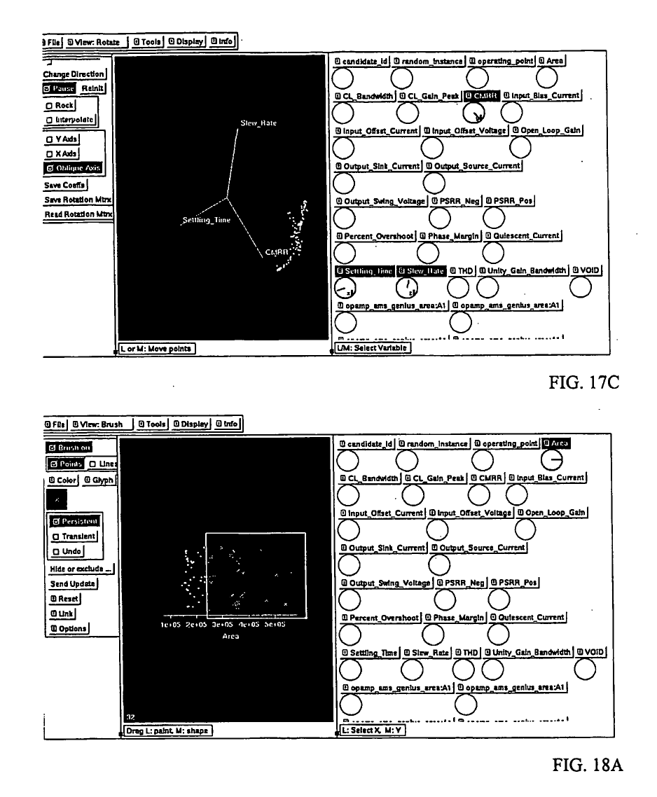

The user now moves to more particular design criteria. For example, the user desires only candidate designs that have an open loop gain >=40 dB, so with open loop gain as one of the axes, he first selects all the points with open loop gain less than 40 dB, as shown in FIG. 13. Then, as described for FIG. 11, the user hides and excludes the newly selected datapoints, to result in the plot displayed in FIG. 14.

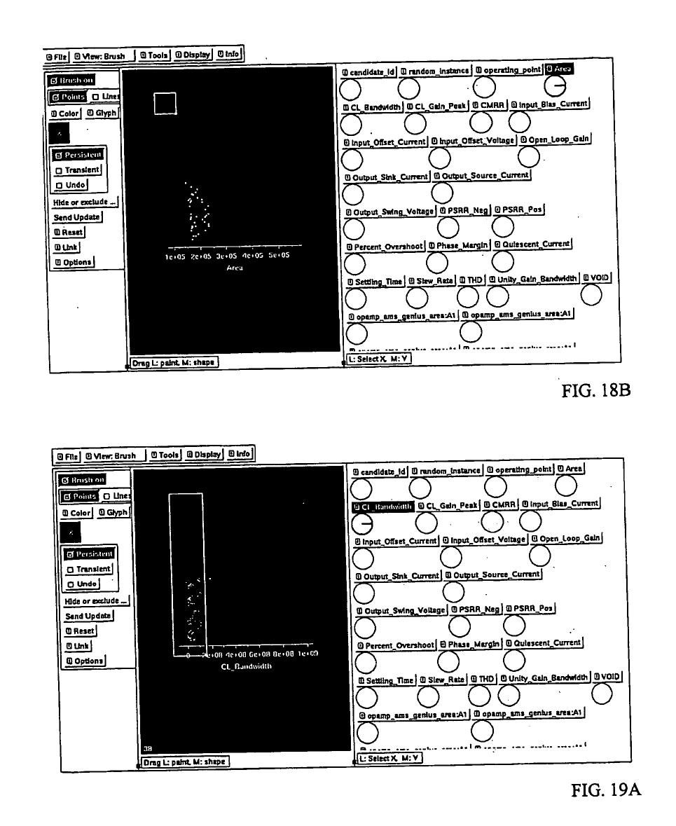

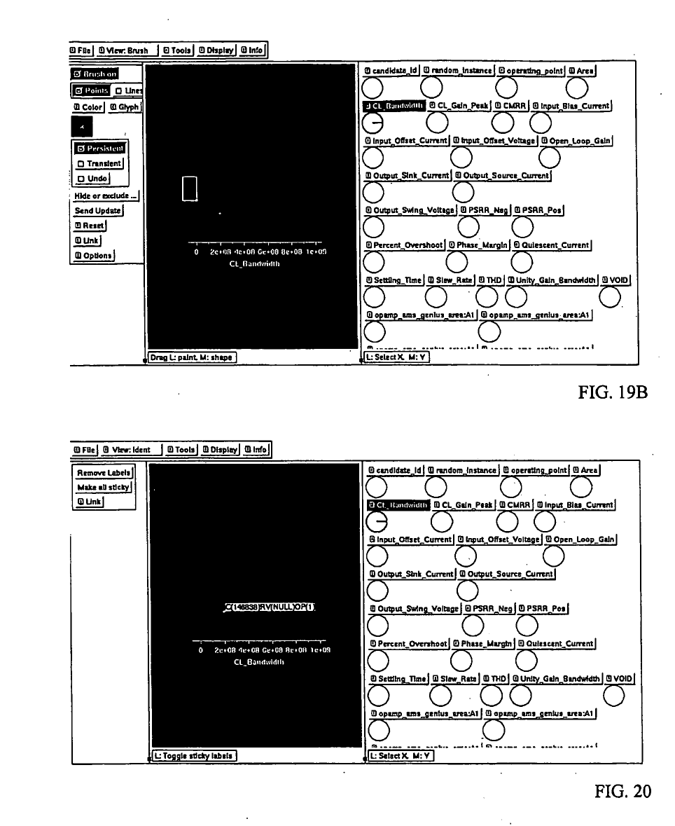

As the user explores relations among selected datapoints, he gains knowledge about the data. For example, as shown he sees that there is a tradeoff between slew rate and settling time in general, as shown in FIG. 15. The user then decides to filter out excessive values of slew rate and excessive values of settling time, resulting in the displayed plot of FIG. 16.

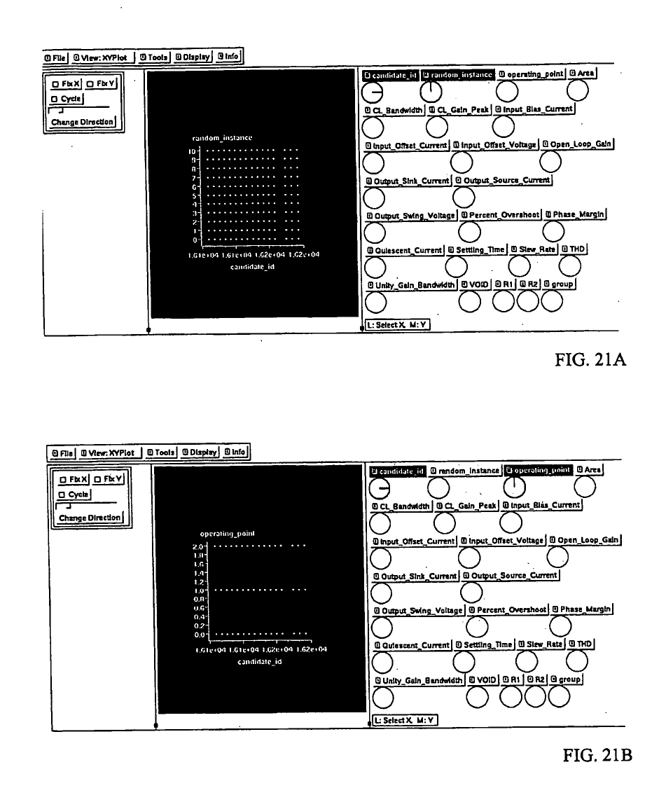

Next, the user wants to discover the tradeoffs between slew rate, settling time, and CMRR, so chooses a 3-D interactive rotation view, and interactively rotates the data, as shown in FIGS. 17A-17C. The user can see, when the CMRR component is hidden, the now-familiar tradeoff between slew rate and settling time. But if he rotates the view, he sees that there exists a tradeoff between all three variables. The user can see that if he removes some points with low CMRR, he will affect the slew rate and settling time performances quite a bit, so, instead, decides not to select based on CMRR at this time.

The designer next considers filtering based on percent overshoot. He sees that slew rate and settling time can still be good when percent overshoot is low, and, therefore, removes all the high percent overshoot data, leaving 71 selected datapoints.

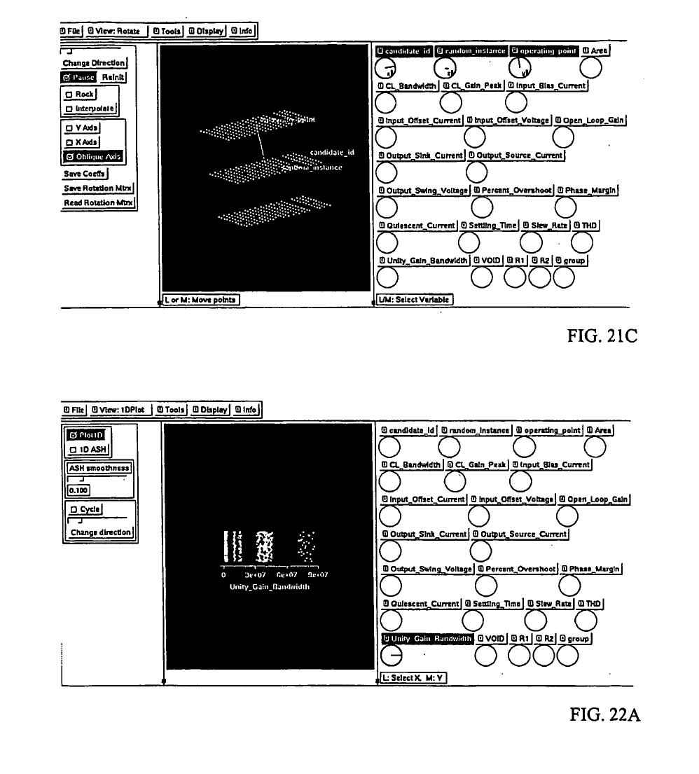

The designer next uses a 1-D dotplot to investigate area, as shown in FIG. 18A. He decides to remove all larger areas by first selecting the data, then hiding it, resulting in the plot of FIG. 18B.

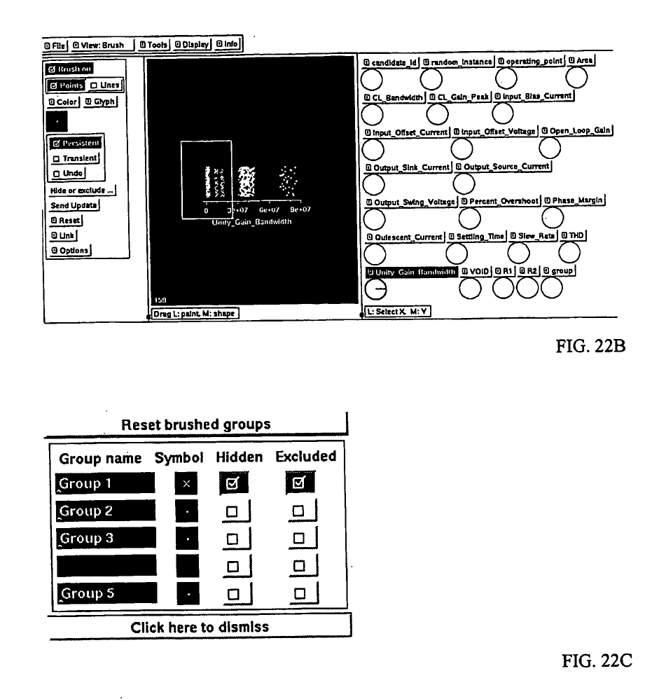

After browsing the data with many views and many different variables, the user decides that final selection based should be based on CL bandwidth, i.e. the design with the best value of CL_bandwidth. Displaying a 1-D plot of CL bandwidth, he first selects the data to hide, then hides it. This results in a single datapoint, as shown in FIGS. 19A-19B. The resultant data point has a tag corresponding to a specific design so that the design of interest can be retrieved, as shown in FIG. 19C.

### EXAMPLE 2

The second example uses parallel coordinate plots, and shows how the user can analyze the effect of random variations in manufacturing, and the effect of different environmental operating conditions.

In FIGS. 21A-21C, we are learning about what sampling took place in this data. In FIG. 21A an x-y plot shows the 17 different candidate designs, each with 11 different random instances. In FIG. 21B, the user sees that there are 3 operating points for each design candidate. In FIG. 21C the user can fully visualize the enumeration of the information with a 3-D plot of candidate id vs operating point vs random instance.

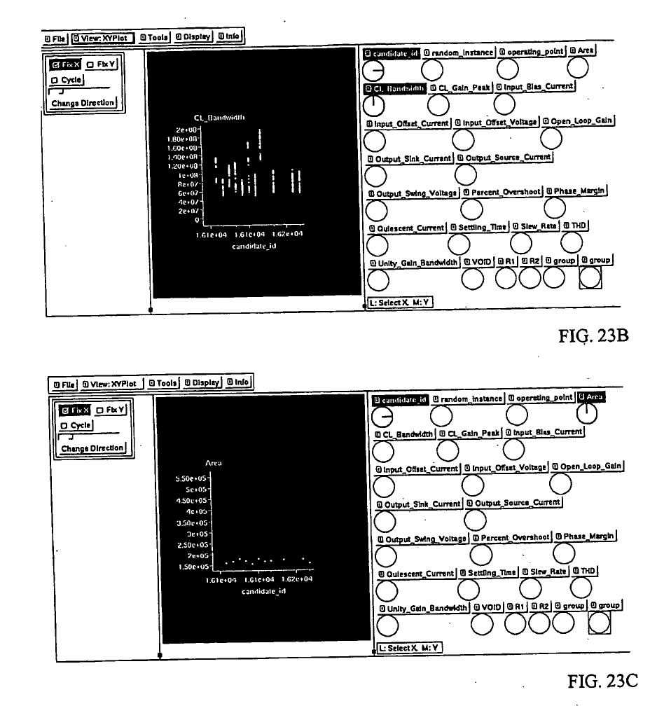

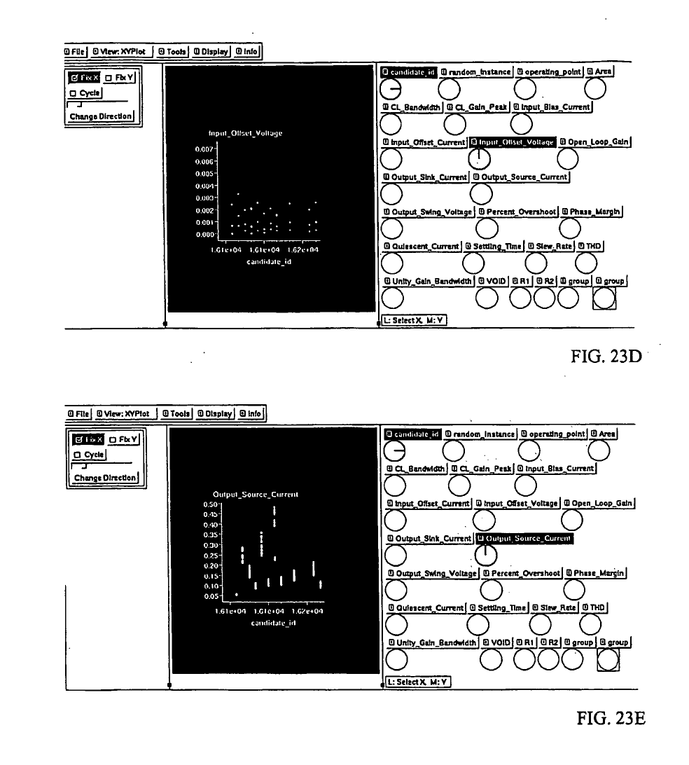

Next, the user cycles through some 1-D plots (which show density as well) to see what circuits the user might want to remove based on performance measures. The user decides to remove all circuits with very low unity gain bandwidth, as shown in FIGS. 22A-22D. The user then looks at x-y plots, in which one axis is candidate id and the other axis is a performance measure. Quite often the effect that the user sees is for each candidate, there are 3 “blobs” of data (one blob per environmental operating point; a blob comprises all the random variations). In FIG. 23A, the user sees that operating point has a very heavy effect on many candidates' input bias current, especially compared to random variations. In FIG. 23B, the user sees that operating point has a less marked effect on CL bandwidth; the effect of operating point and random variations is approximately the same. In FIG. 23C, the user sees that operating point and random variations have near-zero effect on a candidate's area. This is what the user expects. In FIG. 23D, for input offset voltage, the user sees that environmental operating points have an effect, but random variations do not. Of course, different design candidates can have different levels of robustness, as shown in FIG. 23E. For example, the user sees that the candidate on the far left of this x-y plot is quite immune to both random and environmental variations, in terms of output source current. In FIG. 23F, the user sees candidates that perform very poorly for percent overshoot for certain environmental conditions, compared to all the other circuits. In FIG. 23G, the user removes that candidate.

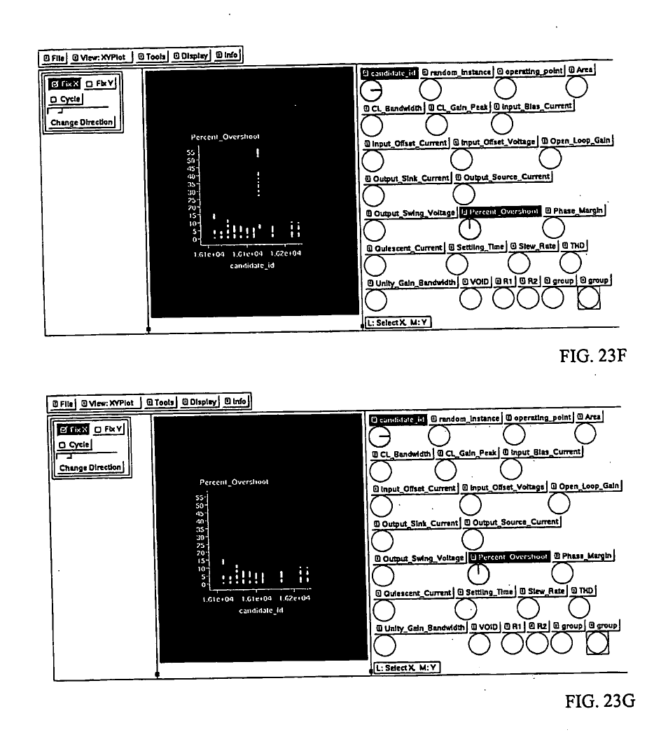

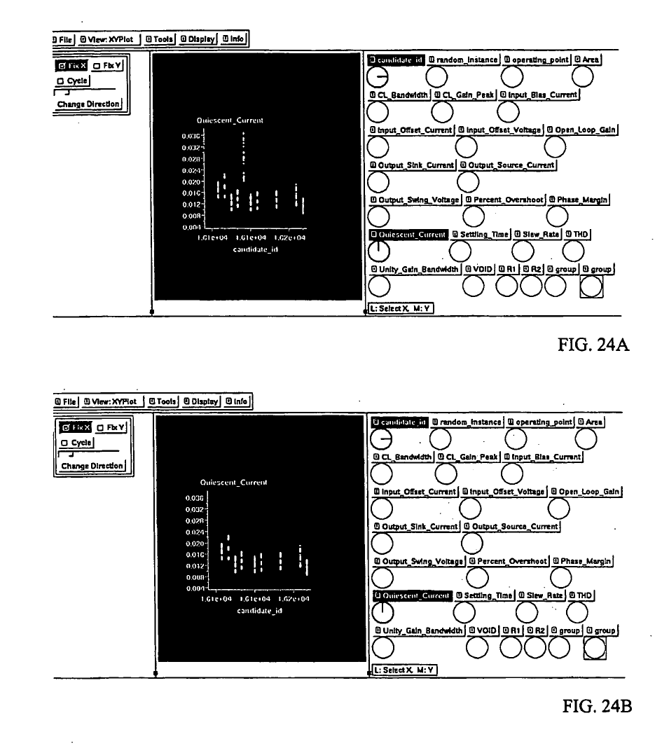

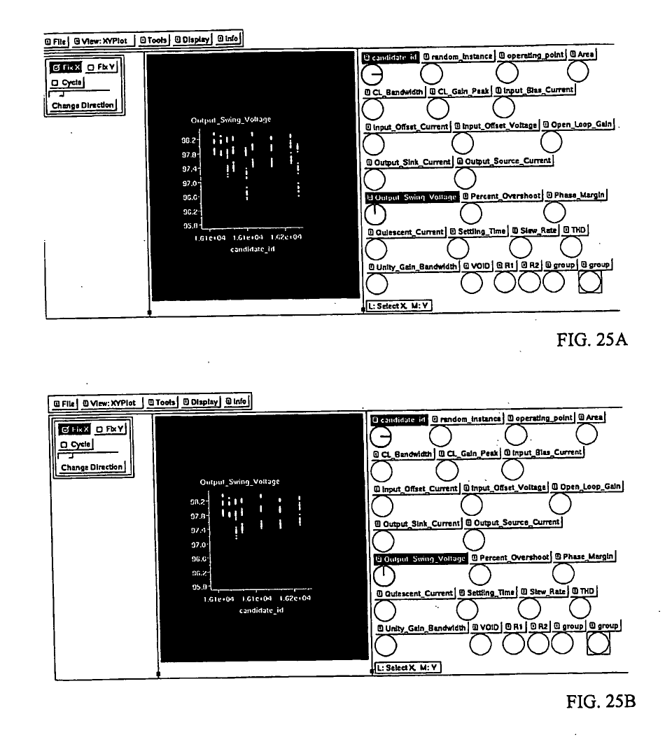

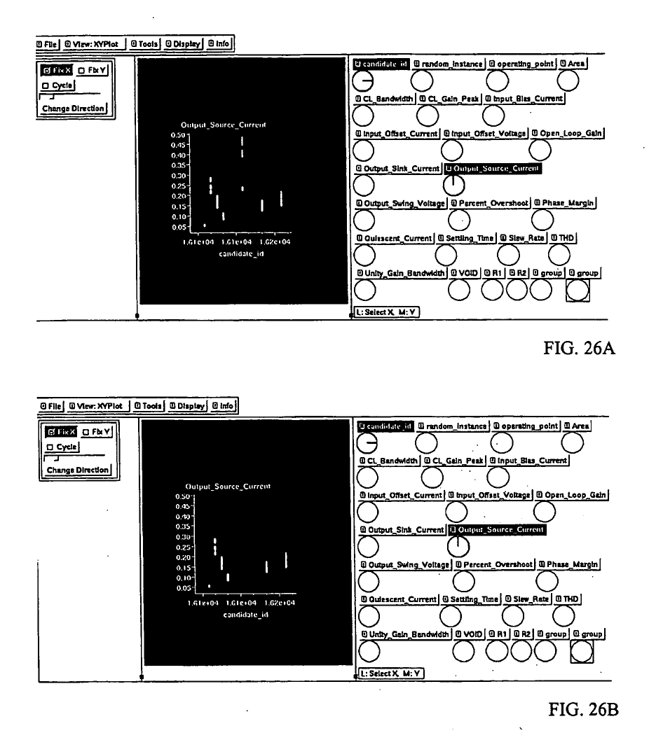

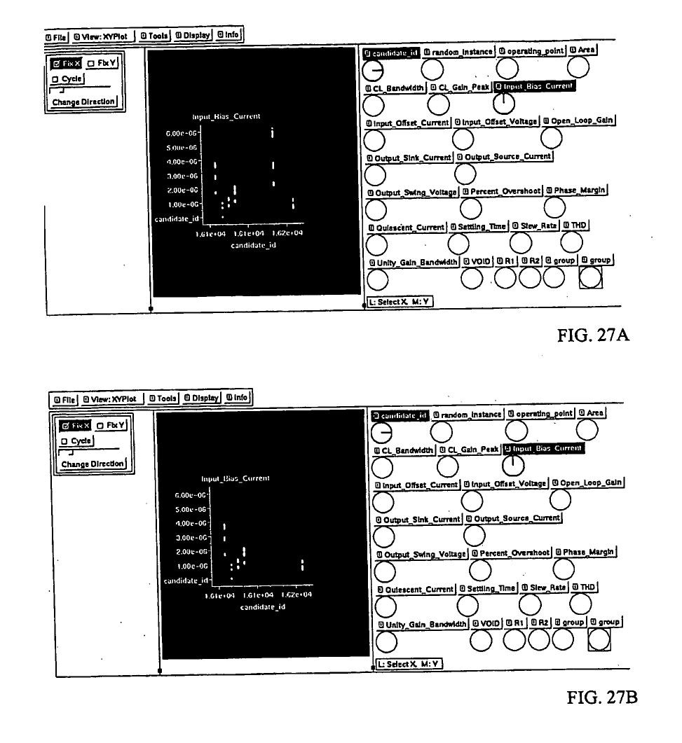

In the reduced set of datapoints, the user next examines the effect of quiescent current, as shown in FIG. 24A. The user sees a candidate which has a quiescent current that is not very robust, so the user removes that candidate, in FIG. 24B. Moving to the plot of FIG. 25A, the user sees two candidates that have output swing voltages that are not very robust, so the user deselects them, as shown in FIG. 25B. In FIGS. 26A-26B, the user sees a candidate that has an output source current that is not very robust, so the user removes that candidate. In FIGS. 27A-27B, the user sees a candidate which has an input bias current that is not very robust, so the user removes that candidate. In FIGS. 28A-28B, the user chooses to remove the two candidates with the highest output sink currents. All these interactive modifications result in a reduced set of four candidate designs.

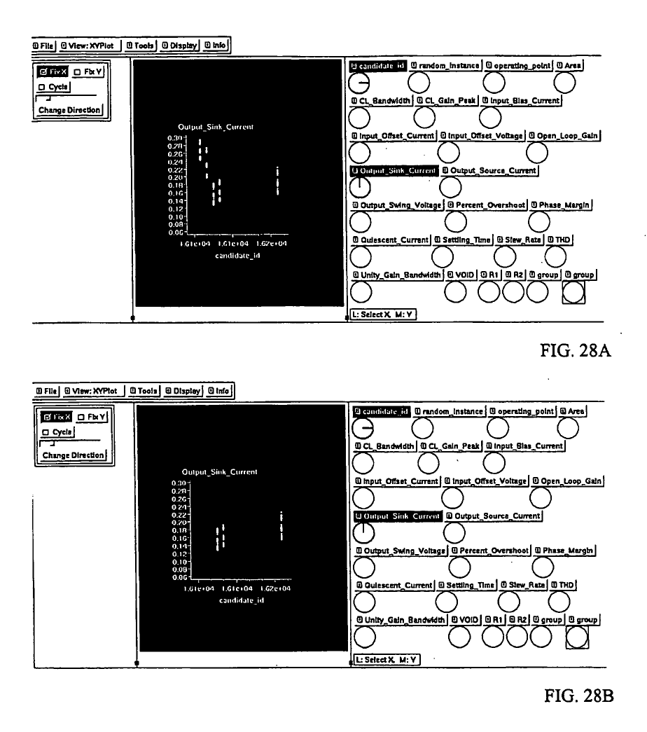

The user next analyzes tradeoffs among the remaining four candidates, using a parallel coordinates plot. In FIG. 29A, the candidates are brushed to each have a different color or shading, and glyph. All four candidates are displayed on the parallel coordinates plot, as shown in FIG. 29B. This plot allows us to understand all dimensions of performance at once for each candidate, to visualize tradeoffs and the effects of random variation in a novel manner. Note that for some performance measures, there is virtually no difference among the candidates, such as area. For other performance measures there is a difference, such as input bias current, input offset current, and input offset voltage. The user can quickly understand performance differences as well: for example, the user can see that the filled-circle candidate clearly has the highest output sink current, but a lower open loop gain.

The user can choose to zero in on just a few performance measures as well for closer analysis. Because area, CL gain peak, percent overshoot, phase margin, settling time, and THD are all approximately the same for the four candidate circuits, the user removes those performance measures from the picture, as shown in FIG. 29C.

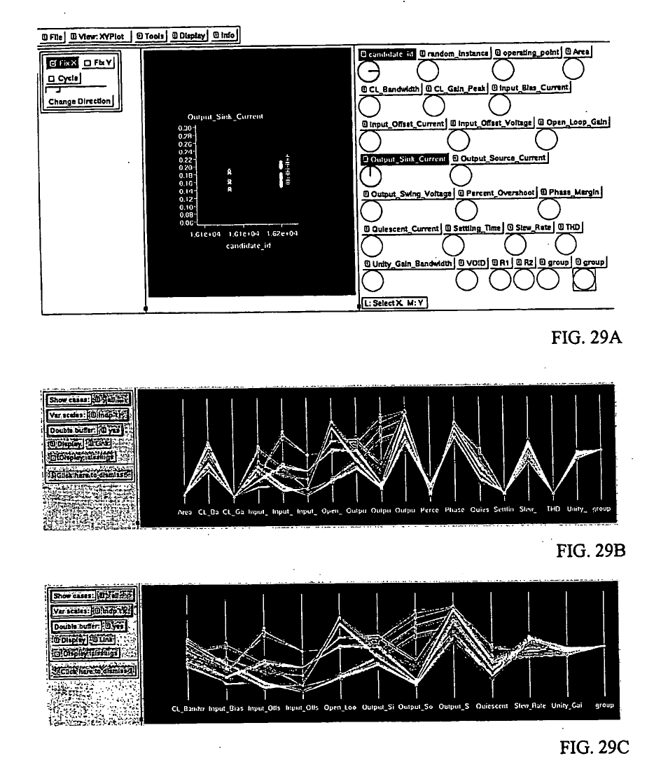

The user can choose to view the performances of one circuit by merely “hiding” the other circuits from view, as shown in FIGS. 30A-30C. This makes it easier to visualize the effects of random variations and environmental conditions across all performance measures at once, for a circuit. The user finds out that, for example, this candidate's open loop gain is quite susceptible to different environmental operating points but not to random variations. The user also can quickly see that output swing voltage is particularly affected by random variations.

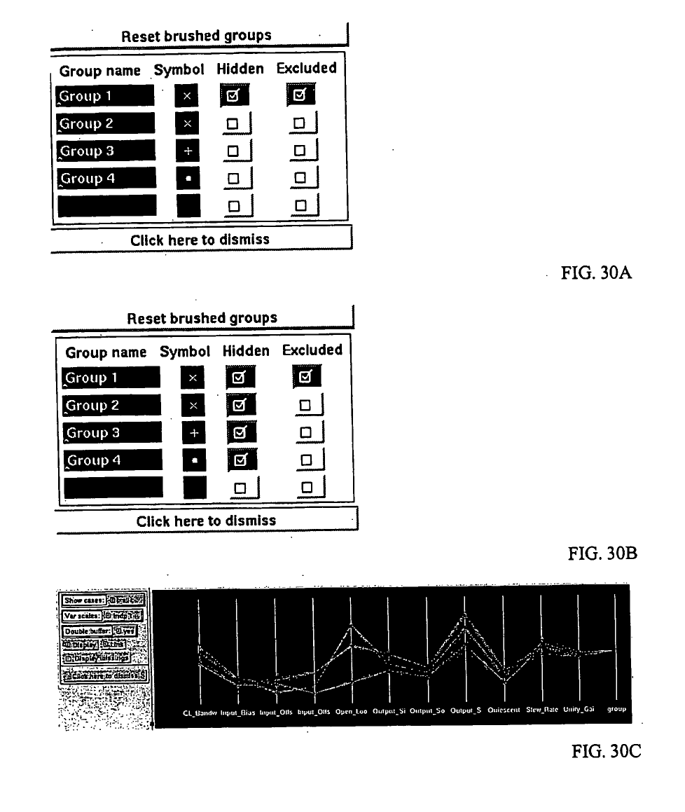

The user can compare two circuits' performances quickly and easily across many performance measures at once with the parallel coordinates plot. The user decides that between these two designs, the user prefers the one with the lower output source current and the lower input bias current, therefore the user will not consider the other design anymore. So the user is left with three design candidates, as shown in FIG. 31.

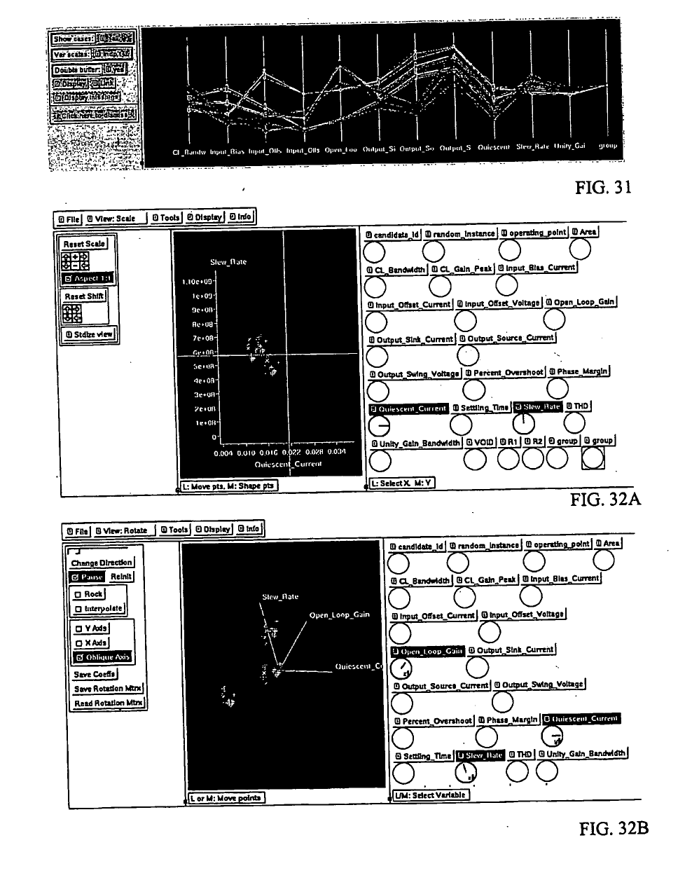

The user can also examine the effects of randomness and different environmental operating conditions with more x-y plots and 3-D plots. The user sees that, for example, open loop gain is affected a lot by environmental operating conditions for all three design candidates, as shown in FIGS. 32A-32C.

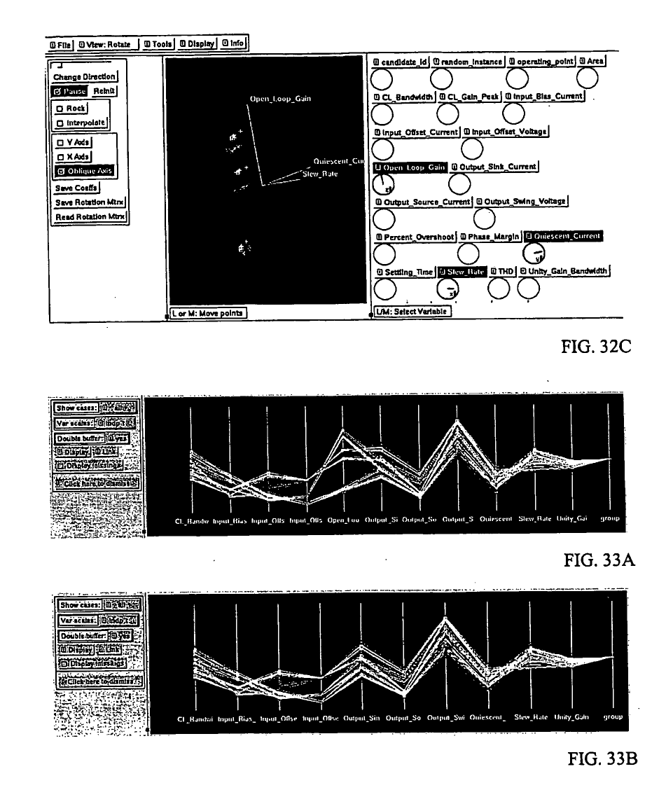

In FIGS. 33A, the user sees that open loop gain is approximately the same for each candidate at each environmental operating point. Therefore the user will not examine the effect of open loop gain in the parallel coordinates plot. This is also the case for input offset current so the user removes that from the parallel coordinates plot as well, resulting in the plots of FIGS. 33B and 33C.

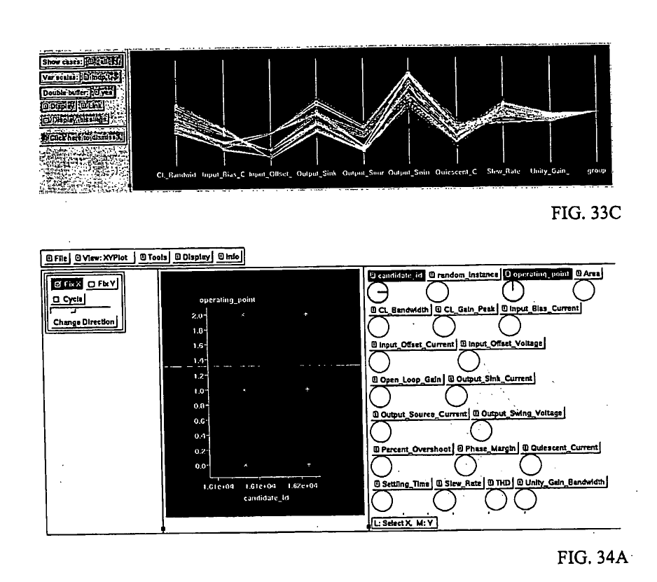

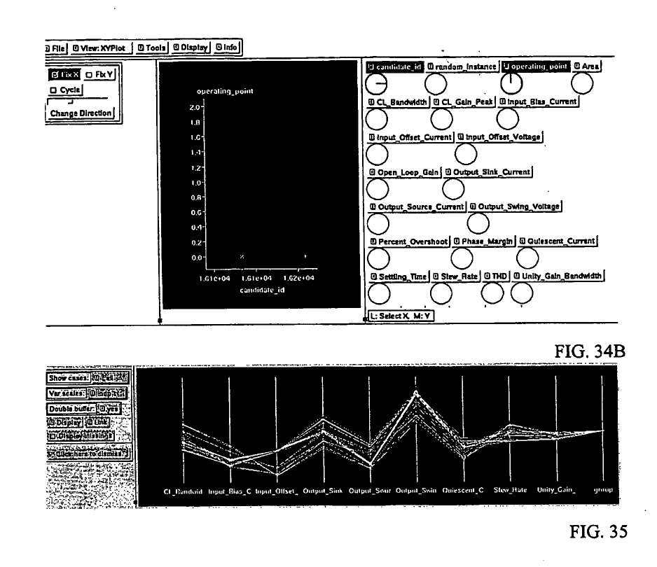

Since the effects of operating points are not going to make a difference in determining the final design any more, the user will only look at one operating point from now on. The user hides the other two, as shown in FIGS. 34A and 34B. In examining the remaining designs on the parallel coordinates plot of FIG. 35, the user decides to choose the design with the lowest output source current and highest CL bandwidth, though the user knows he will not have as low an input bias current. The user has thus selected a final design quickly and efficiently based on his interaction with the various plots.

From the foregoing sections we have presented a visualization system and method for analog circuit design, but it is clear that the method can be used to analyze multidimensional data sets in any design field.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A method for electronic circuit design selection through interactive visualization of optimized design candidates, comprising:
providing a multidimensional dataset of the optimized design candidates, the optimized design candidates being a result of a multi-objective optimization;
displaying the multidimensional dataset of optimized design candidates as a plurality of plots; and
interactively modifying, through interaction with the display of optimized design candidates, at least one of the plurality of plots to identify an evaluation dataset from the multidimensional dataset.

2. The method of claim 1, wherein displaying the plurality of plots includes displaying one-dimensional plots.

3. The method of claim 1, wherein displaying the plurality of plots includes displaying multi-dimensional plots.

4. The method of claim 3, wherein displaying the multi-dimensional plots includes displaying two-dimensional plots.

5. The method of claim 3, wherein displaying the multi-dimensional plots includes displaying three-dimensional plots.

6. The method of claim 3, wherein displaying the multi-dimensional plots includes displaying rotating plots.

7. The method of claim 3, wherein displaying the multi-dimensional plots includes displaying parallel coordinate plots.

8. The method of claim 1, wherein interactively modifying the at least one of the plurality of plots includes applying a filter to the at least one of the plurality of plots.

9. The method of claim 8, wherein applying a filter includes brushing the at least one of the plurality of plots.

10. The method of claim 8, wherein applying a filter includes defining a constraint function to a variable of the multidimensional dataset.

11. The method of claim 10, wherein the constraint function is non-linear.

12. The method of claim 1, wherein interactively modifying the at least one of the plurality of plots includes constructing a mapping of variables.

13. The method of claim 1, wherein interactively modifying the at least one of the plurality of plots includes constructing a mapping for dimensionality reduction.

14. The method of claim 1, wherein interactively modifying the at least one of the plurality of plots includes constructing weighted sums of variables.

15. The method of claim 1, further including:
displaying the evaluation dataset as further evaluation plots; and
interactively modifying the displayed further evaluation plots to select a refined evaluation dataset from the evaluation dataset.

16. The method of claim 1, wherein the multidimensional dataset includes circuit metrics derived from a multiobjective optimization.

17. The method of claim 1, wherein the circuit metrics include analog circuit metrics.

18. A system for electronic circuit design selection through interactive visualization of multidimensional datasets, comprising:
a database for storing a multidimensional dataset;
a display, operatively connected to the database, for displaying the multidimensional dataset as a plurality of plots; and
means for interactively modifying at least one of the plurality of plots to select an evaluation dataset from the multidimensional dataset.
